(19) United States
(12) Patent Application Publication
(10) Pub. No.: US 2025/0214120 A1
(43) Pub. Date: Jul. 3, 2025

(54) SUBSTRATE TREATMENT APPARATUS AND SUBSTRATE TREATMENT METHOD

(71) Applicant: SEMES CO., LTD., Cheonan-si (KR)

(72) Inventors: Hyung Seok KANG, Suwon-si (KR); Joon Ho WON, Suwon-si (KR); Anton KORIAKIN, Suwon-si (KR); Min Woo KIM, Seoul (KR); Geun Su LEE, Suwon-si (KR); Seung Un OH, Cheonan-si (KR); Hee Suk KIM, Cheonan-si (KR)

(73) Assignee: SEMES CO., LTD., Cheonan-si (KR)

(21) Appl. No.: 18/974,963

(22) Filed: Dec. 10, 2024

(30) Foreign Application Priority Data
Dec. 27, 2023 (KR) 10-2023-0193381

(51) Int. Cl. B08B 7/00

(52) U.S. Cl. CPC B08B 7/0021; B08B 7/0071

(57) ABSTRACT

The present invention provides a substrate treatment method. The substrate treatment method may include washing a drying chamber including: wetting a dummy substrate with a chemical in a liquid treatment chamber; washing a treatment space of the drying chamber by loading the dummy substrate wet with the chemical into the drying chamber and then supplying supercritical fluid to the drying chamber; and performing bake treatment to reuse the dummy substrate used to wash the drying chamber.

### CROSS-REFERENCE TO RELATED APPLICATIONS

This application claims priority to and the benefit of Korean Patent Application No. 10-2023-0193381 filed in the Korean Intellectual Property Office on Dec. 27, 2023, the entire contents of which are incorporated herein by reference.

### TECHNICAL FIELD

The present invention relates to a substrate treatment apparatus and a substrate treatment method.

### BACKGROUND ART

Various processes such as photographing, etching, ashing, thin film deposition, and washing processes are performed to manufacture semiconductor devices and flat display panels. The photographing process of these processes sequentially performs coating, exposing, and developing steps. The coating process is a process of coating the surface of a substrate with a photoresist such as a resist. The exposing process is a process of exposing a circuit pattern on a substrate having a photoresist film formed thereon. The developing process is a process of selectively developing an exposed region of a substrate.

The developing process may include a developer supply step, a rinse solution supply step, and a drying step. The developer supply step, the rinse solution supply step, and the drying step sequentially proceed. The developer supply step is a step of developing an exposed region by supplying a developer onto a substrate and the rinse solution supply step is a step of rinsing process byproducts and a remaining developer produced by a developer. The drying step is a step of removing a rinse solution remaining on a substrate by rotating the substrate at a high speed.

Meanwhile, a drying process that uses supercritical fluid was proposed to prevent collapse of a photoresist pattern in the process of drying a substrate by rotating the substrate at a high speed, but there is a problem of reverse contamination of a substrate due to residues in the manufacturing process of a semiconductor device, etc.

### SUMMARY OF THE INVENTION

An objective of the present invention is to provide a substrate treatment apparatus and a substrate treatment method that can prevent contamination of a substrate due to residue and improve the problem of collapse of a pattern.

An objective of the present invention is to provide a substrate treatment apparatus and a substrate treatment method that can improve washing efficiency of a supercritical chamber.

An objective of the present invention is to provide a substrate treatment apparatus and a substrate treatment method that can reuse a dummy substrate used for washing a supercritical chamber and can increase the number of times of reuse.

An objective of the present invention is to provide a substrate treatment apparatus and a substrate treatment method that can automatically wash a supercritical chamber through job creation.

The objectives of the present invention are not limited to the objectives described above and other objectives will be clearly understood by those skilled in the art from the following description.

According to an aspect of the present invention, there may be provided a substrate treatment method including washing a drying including: wetting a dummy substrate with a chemical in a liquid treatment chamber; washing a treatment space of the drying chamber by loading the dummy substrate wet with the chemical into the drying chamber and then supplying supercritical fluid to the drying chamber; and performing bake treatment to reuse the dummy substrate used to wash the drying chamber.

Further, the substrate treatment method may further include: unloading the dummy substrate from a dummy FOUP and loading the dummy substrate into the liquid treatment chamber; and returning the baked dummy substrate to the dummy FOUP.

Further, the chemical wetting the dummy substrate may include an organic solvent.

Further, the supercritical fluid may include carbon dioxide.

Further, heat treatment may be performed on the dummy substrate at 110° C. or higher in the bake treatment.

The washing of the drying chamber may include a pre-mode that is performed before a preset developing process job of substrates is started, a middle mode that is performed during the developing process job of substrates, and a post-mode that is performed after the developing process job of substrates is finished.

Further, different washing numbers of times and washing recipes may be set in accordance with conditions for the pre-mode, the middle mode, and the post-mode, and the washing recipe may include temperature, pressure, the type of chemical, time, the amount of supercritical fluid, and the number of times of repetition of injection and discharge of supercritical fluid.

Further, the pre-mode may have a more number of times of washing than the middle mode and the post-mode.

Further, the drying chamber may be washed every time a predetermined number of sheets of substrates are treated in the middle mode.

Further, the developing process job may include: performing developing treatment by applying a developer to the substrate in the liquid treatment chamber; and performing drying treatment on the developed substrate using supercritical fluid in a drying chamber.

According to another aspect of the present invention, there may be provided a substrate treatment apparatus including: a liquid treatment chamber performing developing treatment by applying a developer to the substrate; a drying chamber performing drying treatment on the developed substrate from the liquid treatment chamber using supercritical fluid; a heat treatment chamber baking the substrate before and after the developing treatment; a dummy FOUP accommodating a dummy substrate; and a controller configured to control cleaning of a treatment space of the drying chamber using the dummy substrate accommodated in the dummy FOUP in accordance with preset conditions.

Further, the controller may be configured to control such that the dummy substrate used to clean the drying chamber is returned to the dummy FOUP after heat treatment in the heat treatment chamber.

Further, the controller may be configured to control washing of the treatment space of the drying chamber by wetting the dummy substrate with a cleaning chemical in the liquid treatment chamber, loading the dummy substrate wet with the cleaning chemical into the drying chamber, and supplying supercritical fluid to the drying chamber.

Further, the cleaning chemical wetting the dummy substrate may include an organic solvent.

Further, the supercritical fluid may include carbon dioxide.

Further, heat treatment may be performed on the dummy substrate at 110° C. or higher in the heat treatment chamber.

Further the controller may be configured to control to perform a pre-mode that washes the treatment space of the drying chamber before a preset developing process job of substrates is started, a middle mode that washes the treatment space of the drying chamber during the developing process job of substrates, and a post-mode that washes the treatment space of the drying chamber after the developing process job of substrates is finished.

According to another aspect of the present invention, there may be provided a substrate treatment method including: performing developing treatment by applying a developer to the substrate in a liquid treatment chamber; performing drying treatment on the developed substrate using supercritical fluid in a drying chamber; and washing the drying chamber, wherein the washing of the drying chamber may include: unloading a dummy substrate from a dummy FOUP and loading the dummy substrate into the liquid treatment chamber; wetting the dummy substrate with a chemical in the liquid treatment chamber; washing a treatment space of the drying chamber by loading the dummy substrate wet with the chemical into the drying chamber and then supplying supercritical fluid to the drying chamber; performing bake treatment to reuse the dummy substrate used to wash the drying chamber; and returning the baked dummy substrate to the dummy FOUP.

Further, the washing of the drying chamber may include a pre-mode that is performed before a preset developing process job of substrates is started, a middle mode that is performed during the developing process job of substrates, and a post-mode that is performed after the developing process job of substrates is finished.

Further, the chemical wetting the dummy substrate may include an organic solvent, the supercritical fluid may include carbon dioxide, and heat treatment may be performed on the dummy substrate at 110° C. or higher in the bake treatment.

Further, different washing numbers of times and washing recipes may be set in accordance with conditions for the pre-mode, the middle mode, and the post-mode, the washing recipe may include temperature, pressure, the type of chemical, time, the amount of supercritical fluid, and the number of times of repetition of injection and discharge of supercritical fluid, and the pre-mode may perform a more number of times of washing than the middle mode and the post-mode.

According to an embodiment of the present invention, it is possible to prevent contamination of a substrate by residues in the drying chamber and reduce collapse of a pattern.

According to an embodiment of the present invention, it is possible to improve the washing efficiency of the drying chamber.

According to an embodiment of the present invention, it is possible to reuse a dummy substrate used to wash the drying chamber and increase the number of time of reuse.

According to an embodiment of the present invention, it is possible to automatically wash the drying chamber through developing process job creation and expect an effect of reducing the number of times of stop of a unit for PM.

Effects of the present invention are not limited to those described above and effects not stated above will be clearly understood to those skilled in the art from the specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 shows a substrate treatment apparatus according to an embodiment of the present invention.

FIGS. 2 and 3 show the substrate treatment module of FIG. 1.

FIG. 4 shows the liquid treatment unit of FIGS. 2 and 3.

FIG. 5 shows the supercritical treatment unit of FIGS. 2 and 3.

FIG. 6 shows the heat treatment module of FIG. 1.

FIGS. 7 and 8 show another embodiment of FIG. 6.

FIG. 9 is a flowchart illustrating a washing process of a drying chamber.

FIG. 10 is a table showing a cleaning recipe according to development process job reference time points.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

A wafer is exemplarily described as a target of treatment in this embodiment. However, the technical spirit of the present invention can be applied even to devices that are used to treat other kinds of substrates other than a wafer as a treatment target.

Embodiments of the present invention are described hereafter in detail with reference to the accompanying drawings.

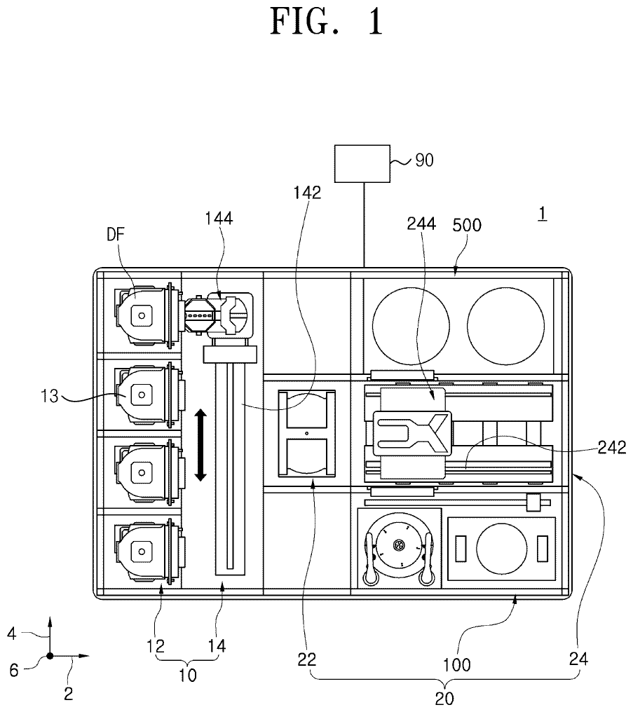

FIG. 1 is a plan view showing a substrate treatment apparatus according to an embodiment of the present invention. Referring to FIG. 1, a substrate treatment facility 1 has an index unit 10 and process performing unit 20. The index unit 10 has a load port 12 and an index frame 14. The load port 12, the index frame 14, and the process performing unit 20 are sequentially arranged in a line. Hereafter, the direction in which the load port 12, the index frame 14, and the process performing unit 20 are arranged is referred to as a first direction 2, and when seen from above, a direction perpendicular to the first direction 2 is referred to as a second direction 4, and a direction perpendicular to a plane including both of the first direction 2 and the second direction 4 is referred to as a third direction 6.

Carriers 13 having substrates W therein are seated in the load port 12. A plurality of load ports 12 is provided and is arranged in a line in the second direction 4. The number of the load ports 12 may be increased or decreased, depending on the process efficiency, a footprint condition, etc. of the process performing unit 20. Multiple slots (not shown) for accommodating substrates W disposed in parallel with the ground are formed at the carrier 13. A Front Opening Unified Pod (FOUP) may be used as the carrier 13. Meanwhile, a dummy carrier DF accommodating a dummy substrate that is used for washing a chamber may be seated in the load port 12.

The index frame 14 transfers substrates between the carriers 13 seated in the load ports 13 and a buffer unit 22. An index rail 142 and an index robot 144 are provided at the index frame 14. The longitudinal direction of the index rail 142 is provided in parallel with the second direction 4. The index robot 144 is installed on the index rail 142 and is straightly moved along the index rail 142 in the second direction 4. The index robot 144 may have a base, a body, and an index arm. The base is installed to be movable along the index rail 142. The body is coupled to the base and may be provided to be movable in the third direction 6 on the base. Further, the body may be provided to be rotatable on the base. The index arm is coupled to the body and may be provided to be movable forward and backward with respect to the body. A plurality of index arms may be provided to be individually driven. The index arms may be disposed to be stacked and spaced apart from each other in the third direction 6. Some of the index arms may be used when transferring substrates W from the process performing unit 20 to the carriers 13 and the others may be used when transferring substrates W from the carriers 13 to the process performing unit 20. This can prevent particles produced from a substrate W before a process is performed when the substrate W is loaded and unloaded from sticking to the substrate W after a process is performed.

The process performing unit 20 may include a buffer unit 22, a transfer module 24, a substrate treatment module 100, and a heat treatment module 500. The longitudinal direction of the transfer module 24 may be provided in parallel with the first direction 2. The substrate treatment module 100 and the heat treatment module 500 may be disposed on sides of the transfer module 24.

For example, substrate treatment modules 100 may be disposed at a side of the transfer module 24 and heat treatment modules 500 may be disposed at the opposite side. The substrate treatment modules 100 and the heat treatment modules 500 may be provided at opposite sides with the transfer module 24 therebetween. Some of the substrate treatment modules 100 and the heat treatment modules 500 may be disposed in the longitudinal direction of the transfer module 24. Further, some of the substrate treatment modules 100 and the heat treatment modules 500 may be disposed to be stacked on each other. That is, the substrate treatment modules 100 and the heat treatment modules 500 may be disposed in an array of A×B at both sides of the transfer module 24. In this case, A is the number of the treatment modules provided in a line in the first direction 2 and B is the number of the treatment modules provided in a line in the third direction 6. The numbers of the substrate treatment modules 100 and the heat treatment modules 500 may be increased or decreased in consideration of the footprint or the process efficiency of the substrate treatment apparatus 1.

The disposition of the substrate treatment modules 100 and the heat treatment modules 500 based on the transfer module 24 may be opposite to the above description. Alternatively, the substrate treatment modules 100 and the heat treatment modules 500 may be disposed at both sides of the transfer module 24, respectively, and the substrate treatment modules 100 and the heat treatment modules 500 may be symmetrically provided at a side and another side of the transfer module 24 with the transfer module 24 therebetween. The substrate treatment modules 100 may be disposed close to the buffer unit 22 in comparison to the heat treatment modules 500. Alternatively, the heat treatment modules 500 may be disposed close to the buffer unit 22 in comparison to the substrate treatment modules 100. Further, the substrate treatment module 100 and the heat treatment module 500 may be provided in a single layer at a side or both sides of the transfer module 24.

The buffer unit 22 may be disposed between the index frame 14 and the transfer module 24. The buffer unit 22 can provide a space in which substrates W stay before the substrates W are transferred between the transfer module 24 and the index frame 14. A slot (not shown) in which a substrate W is placed may be provided in the buffer unit 22. A plurality of slots (not shown) may be provided to be spaced apart from each other in the third direction 6. The buffer unit 22 may be open on the surface facing the index frame 14 and the surface facing the transfer module 24.

The transfer module 24 transfers substrates W between the buffer unit 22 and the substrate treatment module 100, between substrate treatment modules 26, and between the substrate treatment module 100 and the heat transfer module 500. A guide rail 242 and a main robot 244 are provided to the transfer module 24. The longitudinal direction of the guide rail 242 is disposed in parallel with the first direction 2. The main robot 244 is installed on the guide rail 242 and is straightly moved on the guide rail 242 in the first direction 2. The main robot 244 may have a base, a body, and a main arm. The base is installed to be movable along the guide rail 242. The body is coupled to the base and may be provided to be movable in the third direction 6 on the base. Further, the body may be provided to be rotatable on the base. The main arm is coupled to the body and may be provided to be movable forward and backward with respect to the body. A plurality of main arms may be provided to be individually driven. The main arms may be disposed to be stacked and spaced apart from each other in the third direction 6.

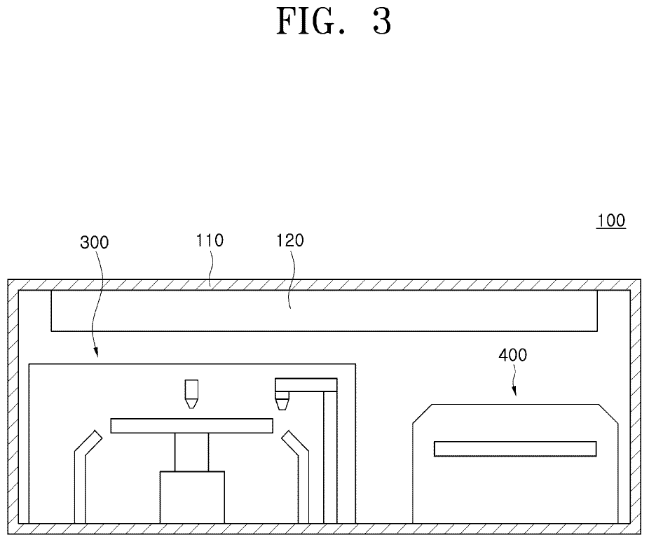

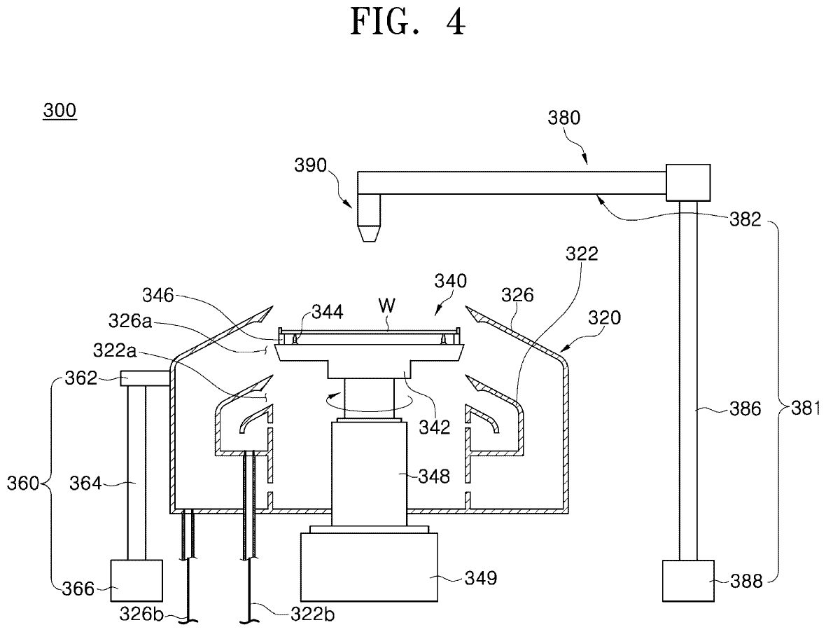

FIGS. 3 and 4 show the substrate treatment module 100 of FIG. 1. FIG. 3 is a plan view showing the substrate treatment module 100 according to an embodiment of the present invention and FIG. 4 is a side cross-sectional view showing the substrate treatment module 100 according to an embodiment of the present invention.

The substrate treatment module 100 may include a liquid treatment unit 300 that performs a liquid treatment process on substrates W and a supercritical treatment unit 400 that performs treatment using supercritical fluid on substrates W. The liquid treatment unit 300 of the units can perform a liquid treatment process on substrates W. The liquid treatment unit 300 may have different structures, depending the kinds of liquid treatment that is performed. Selectively, the substrate treatment modules 100 may be divided into a plurality of groups such that the components provided in the substrate treatment modules 100 in the same group are the same as each other and the components and structures provided in the substrate treatment modules 100 in different groups are different from each other.

In this embodiment, the liquid treatment process of a substrate is described as a developing process. The liquid treatment process is not limited to a developing process and may be variously applied to coating, washing, etching, etc.

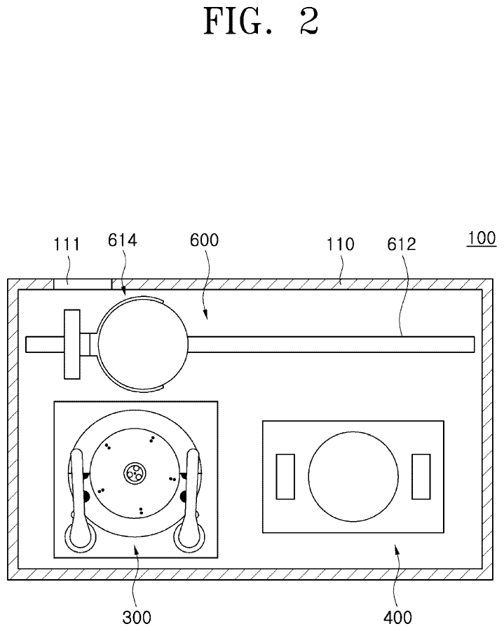

FIGS. 2 and 3 show the substrate treatment module 100 of FIG. 1. FIG. 2 is a plan view showing the substrate treatment module 100 according to an embodiment of the present invention and FIG. 3 is a side cross-sectional view showing the substrate treatment module 100 according to an embodiment of the present invention.

Referring to FIGS. 2 and 3, the substrate treatment module 100 includes a housing 110, a liquid treatment unit 300, and a supercritical treatment unit 400.

The housing 110 provides an internal space in which the liquid treatment unit 300 and the supercritical treatment unit 400 are disposed. For example, the housing 110 may be provided in a rectangular prism shape. The housing 110 may include an entrance 111 formed on the surface facing the transfer module 24. The entrance 111 provides a passage for movement of substrates W.

In this specification, an example in which the housing 110 has one entrance 111 formed in a region adjacent to the liquid treatment unit 300 is shown, but the position of the entrance 111 is not limited thereto and the housing 110 may include a plurality of entrances. For example, one more entrance may be formed in a region adjacent to the supercritical treatment unit 400 on the surface facing the transfer module 24, and substrates W can be loaded into the housing 110 through the entrance adjacent to the liquid treatment unit 300 and can be unloaded out of the housing 110 through the entrance adjacent to the supercritical treatment unit 400.

In the housing 110, the liquid treatment unit 300 and the supercritical treatment unit 400 may be sequentially disposed in a line in the first direction 2.

The substrate treatment module 100 may further include a transfer unit 600 for transferring substrates W in the substrate treatment module 100. The transfer unit 600 can receive substrates W from the transfer module 24 and deliver substrates W to the liquid treatment unit 300 and the supercritical treatment unit 400. The transfer unit 600 may include a transfer rail 612 and a transfer member 614 that transfers substrates W along the transfer rail 612.

The longitudinal direction of the transfer rail 612 may be provided in parallel with the direction (first direction) in which the liquid treatment unit 300 and the supercritical treatment unit 400 are disposed. The transfer member 614 may have a base, a body, and a hand. The base is installed to be movable along the transfer rail 612. The body is coupled to the base and provided to be rotatable on the base. The hand is coupled to the body, supports a substrate W, and may be provided to be movable forward and backward with respect to the body.

The transfer unit 600 can transfer substrates W in the substrate treatment module 100 in accordance with a process order and can load and unload substrates W into and out of the liquid treatment unit 300 and the supercritical treatment unit 400.

For example, the transfer member 614 can receive substrates W from the main robot 24 and load the substrates W into the liquid treatment unit 300 and can unload substrates W that have undergone liquid treatment by the liquid treatment unit 300 from the liquid treatment unit 300 and then transfer the substrates W to the supercritical treatment unit 400. Substrates W that have undergone supercritical treatment can be unloaded out of the supercritical treatment unit 400 and then delivered to the main robot 244 by the transfer member 614. While a treatment process of a substrate is performed by the treatment units, the transfer member 614 can stand by outside the treatment unit and the hand of the transfer member 614 can move forward and backward with respect to the body to load or unload substrates W into or out of the treatment units.

Since some operations of the main robot 214 is replaced by the transfer unit 600, so the number of substrates W that can be transferred by the main robot 244 for the same time is increased and the number of substrates W that can be treated by the substrate treatment apparatus1 is increased, so the output per hour of the facility can be increased. Further, the tact time that is consumed to transfer substrates W between the treatment units can be reduced. Further, while continuous processes (developing-washing/drying) are performed on a substrate W, the substrate W is transferred in the housing 110, in which an environment with predetermined temperature and predetermined humidity is maintained, by the transfer unit 600 without passing through the transfer module 24, so environment variation for substrates is minimized, whereby deterioration of the quality of substrates W due to an environmental difference can be prevented and the process ability of the facility can be improved.

Meanwhile, the substrate treatment module 100 may not include a separate transfer unit 600 and substrates W may be transferred in the substrate treatment module 100 by the main robot 242. In this case, entrances may be formed on the housing 110 at both of positions corresponding to the liquid treatment unit 300 and the supercritical treatment unit 400, respectively. Alternatively, the entrance formed on the housing 110 may be formed with a length that can cover the section from the liquid treatment unit 300 to the supercritical treatment unit 400.

The substrate treatment module 100 may further include an airflow supply unit 120 that forms airflow in the housing 110.

For example, the airflow supply unit 120 may be a Fan Filter Unit (FFU) in which a filter and a fan are modularized into one unit. The airflow supply unit 120 is provided at the upper portion of the housing 110 and supplies air to the internal space of the housing 110, thereby being able to generate downflow. The air that is supplied to the internal space by the airflow supply unit 120 may be Clean Dry Air (CDA) adjusted in temperature and humidify. Though not shown in detail, a vent for exhausting airflow in the housing 110 may be formed at the lower portion of the housing 110. The air that is supplied to the internal space by the airflow supply unit 120 may include inert gas such as nitrogen. Meanwhile, the airflow supply unit 120 may be provided on a side of the housing 110 and may be configured to form horizontal airflow. In this configuration, a vent may be formed on a side corresponding to the side on which the airflow supply unit 120 is provided.

An environment with predetermined temperature and humidity can be formed and maintained in the substrate treatment module 100 by the airflow supply unit 120.

FIG. 4 shows the liquid treatment unit 300 of FIGS. 2 and 3. Referring to FIG. 4, the liquid treatment unit 300 includes a treatment container 320, a supporting unit 340, an elevation unit 360, and a liquid discharge unit 380. The liquid treatment unit 300 can perform a developing process of removing a portion of a photoresist by supplying a developer to obtain a pattern on a substrate W. The liquid treatment unit 300 can remove a region to which light is emitted of a photoresist on a substrate W. In this case, a region to which light is emitted of a protective film can also be removed. Only regions to which light is not emitted of regions of a photoresist and a protective film may be removed, depending on the kind of the photoresist that is used.

The treatment container 320 provides a treatment space in which substrates are treated. The treatment container 320 has a tub shape with an open top. The treatment container 320 has an inner recovery tub 322 and an outer recovery tub 326. The recovery tubs 322 and 326 recover different treatment liquids from liquids used in a process. The inner recovery tub 322 is provided in a ring shape surrounding the supporting unit 340 and the outer recovery tub 326 is provided in a ring shape surrounding the inner recovery tub 322. The internal space 322a of the inner recovery tub 322 and the inner recovery tub 322 function as a first inlet through which treatment liquid flows into the inner recovery tub 322. The space 326a between the inner recovery tub 322 and the outer recovery tub 326 function as a second inlet through which treatment liquid flows into the outer recovery tub 326. According to an embodiment, the inlets 322a and 326a may be positioned at different heights. Recovery lines 322b and 326b are connected to the lower surfaces of the recovery tub 322 and 326, respectively. Treatment liquids flowing in the recovery tub 322 and 326 can be provided to a treatment liquid recycle system (not shown) at the outside through the recovery lines 322b and 326b and can be reused.

The supporting unit 340 supports substrates W in the treatment space. For example, the supporting unit 340 may be provided as a spin chuck that supports and rotates substrates W during a process. The supporting unit 340 has a supporting body 342, a supporting pin 344, a chuck pin 346, and a rotation driving member. The supporting body 342 has an upper surface and a lower surface that are provided substantially in a circular shape. The lower surface has a smaller diameter than the upper surface. The upper surface and the lower surface are positioned such that the center axes coincide with each other.

A plurality of supporting pins 344 is provided. The supporting pins 344 are disposed with predetermined intervals at the edge of the upper surface of the supporting body 342 and protrude upward from the supporting body 342. The supporting pins 344 are disposed to have entirely a ring shape through a combination thereof. The supporting pins 333 support the edge of the rear face of a substrate W such that the substrate W is spaced a predetermined distance apart from the upper surface of the supporting body 342.

A plurality of chuck pins 346 is provided. The chuck pins 335 are disposed far from the center of the supporting body 342 in comparison to the supporting pins 344. The chuck pins 346 are provided to protrude upward from the supporting body 342. When the supporting unit 340 is rotated, the chuck pins 335 support the side of a substrate W to prevent lateral separation from the position. The chuck pins 346 are provided to be able to straightly move between an outer position and an inner position in the radial direction of the supporting body 342. The outer position is a position far from the center of the supporting body 342 in comparison to the inner position. When a substrate W is loaded or unloaded onto or from the supporting unit 340, the chuck pins 346 is positioned at the outer position, and when a process is performed on a substrate W, the chuck pins 346 is positioned at the inner position. The inner position is a position where the chuck pins 346 and the side of a substrate W come in contact with each other and the outer position is a position where the chuck pin 346 and a substrate W are spaced from each other.

The rotation driving member 348, 349 rotates the supporting body 342. The supporting member 342 can be rotated around its center axis by the rotation driving member 348, 349. The rotation driving member 348, 349 includes a supporting shaft 348 and a driving unit 349. The supporting shaft 348 has a cylindrical shape facing the third direction 6. The upper end of the supporting shaft 348 is coupled and fixed to the lower surface of the supporting body 342. According to an embodiment, the supporting shaft 348 may be coupled and fixed to the center of the lower surface of the supporting body 342. The driving unit 349 provides a driving force to rotate the supporting shaft 348. The supporting shaft 348 is rotated by the driving unit 349 and the supporting body 342 can be rotated with the supporting shaft 348.

The elevation unit 360 straightly moves the treatment container 320 in the up-down direction. Since the treatment container 320 is moved up and down, the height of the treatment container 320 relative to the supporting unit 340 is changed. The elevation unit 360 has a bracket 362, a moving shaft 364, and an actuator 366. The bracket 362 is installed and fixed on the outer wall of the treatment container 320 and the moving shaft 364 that is moved in the up-down direction is coupled and fixed to the actuator 366. When a substrate W is placed on the supporting unit 340 or lifted from the supporting unit 340, the treatment container 320 is moved down such that the supporting unit 340 protrudes upward from the treatment container 320. Further, when a process proceeds, the height of the treatment container 320 is adjusted such that treatment liquid can flow into the recovery tub 360, depending on the kind of the treatment liquid supplied to a substrate W. Selectively, the elevation unit 360 can move the supporting unit 340 in the up-down direction.

The liquid discharge unit 380 supplies treatment liquid to substrates W. A plurality of liquid discharge units 380 may be provided and they can provide different kinds of treatment liquid. For example, they may include a developer discharge unit for supplying a developer to a substrate W and a washing liquid discharge unit for supplying washing liquid. The liquid discharge unit 380 includes a moving member 381 and a nozzle 390.

The moving member 381 moves the nozzle 390 to a process position and a standby position. In this case, the process position is a position facing a substrate W supported on the substrate supporting unit 340 and the standby position is defined as a position where the nozzle 390 departs from the process position. According to an embodiment, the process position includes a pre-treatment position and a post-treatment position. The pre-treatment position is a position where the nozzle 390 supplies treatment liquid to a first supply position and the post-treatment position is a position where the nozzle 390 supplies treatment liquid to a second supply position. The first supply position may be a position close to the center of a substrate W in comparison to the second supply position and the second supply position may be a position including an end of a substrate. Selectively, the second supply position may be a region adjacent to an end of a substrate.

The moving member 381 includes a supporting shaft 386, an arm 382, and an actuator 388. The supporting shaft 386 is positioned at a side of the treatment container 320. The supporting shaft 386 has a rod shape having a longitudinal direction going in the third direction 3. The supporting shaft 386 is provided to be rotatable by the actuator 388. The supporting shaft 386 is provided to be movable up and down. The arm 382 is coupled to the upper end of the supporting shaft 386. The arm 382 vertically extends from the supporting shaft 386. The nozzle 390 is coupled and fixed to the end of the arm 382. As the supporting shaft 386 is rotated, the nozzle 390 can swing with the arm 382. The nozzle 390 can move to the process position and the standby position by swinging. Selectively, the arm 382 may be provided to be movable forward and backward in the longitudinal direction thereof. When seen from above, the movement path of the nozzle 390 may coincide with the center axis of a substrate W at the process position.

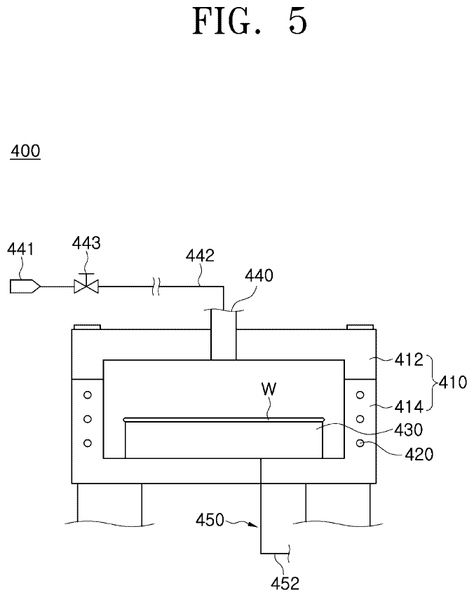

FIG. 5 schematically shows an embodiment of the supercritical treatment unit 400 of FIGS. 2 and 3.

According to an embodiment, the supercritical treatment unit 400 can remove a developer on a substrate W using supercritical fluid. The supercritical treatment unit 400 may include a body 410, a supporting member 430, a fluid supply member 440, and an exhaust member 450.

the body 410 can provide a treatment space in which supercritical treatment processes (e.g., washing and drying) are performed. The body 410 has a first body 412 and a second body 414, and the first body 412 and the second body 414 can provide a treatment space by combining with each other. For example, the first body 412 and the second body 414 are disposed at positions facing each other, and at least one of the first body 412 and the second body 414 can be moved up and down by a separate driving member (not shown). When the first body 412 and the second body 414 are spaced from each other, the treatment space is opened, and in this case, a substrate W can be loaded or unloaded. When a process proceeds, the first body 412 and the second body 414 move close to each other and come completely in close contact with each other, whereby the treatment space can be sealed from the outside.

Meanwhile, the body 410 may be provided such that the position of one of the first body 412 and the second body 414 is fixed and the other one of which the position is not fixed is moved by a chamber driving member (not shown).

The supercritical treatment unit 400 may include heating members 420. The heating members 420 may be installed to be embedded in the wall of the body 410. The heating members 420 can heat the inside of the body 410 such that fluid supplied to the internal space of the body 410 maintains a supercritical state. The heating members 420, for example, may be provided as heaters that is provided with power from the outside and generates heat.

The supporting member 430 is disposed in the treatment space of the body 410 and supports a substrate W. A substrate W loaded into the treatment space of the body 410 is placed on the supporting member 430, and for example, the substrate W may be supported with a pattern surface facing up.

The fluid supply member 440 can supply fluid to the treatment space of the body 410. The fluid may be supplied to the treatment space in a supercritical state. Alternatively, fluid may be supplied to the treatment space in a gas state and then changed in phase into the supercritical state in the treatment space. For example, the fluid that is supplied may be carbon dioxide.

The fluid supply member 440 may be connected with a fluid supplier 441 through a supply line 442. A valve 443 for adjusting the flow rate of drying fluid that is supplied into the body 410 may be installed in the supply line 442. The fluid supply member 440 is provided in the upper wall of the body 410 and can supply supercritical fluid to a substrate W supported by the supporting member 430. The fluid supply member 440 can spray supercritical fluid to the center region of a substrate W. For example, the fluid supply member 440 may be positioned right over the center of a substrate W supported by the supporting member 430. Accordingly, supercritical fluid that is sprayed to a substrate W reaches the center region of the substrate W and spreads to the edge region, whereby the supercritical fluid can be uniformly provided to the entire region of the substrate S. Meanwhile, the fluid supply member 440 may be further provided in the lower wall of the body 410.

The exhaust member 450 can exhaust supercritical fluid from the body 410. The exhaust member 450 may be formed in the lower wall of the body 410. The exhaust member 450 may include an exhaust line 452 for exhausting used supercritical fluid from the treatment space of the body 410. Though not shown in detail, a valve for adjusting the flow rate of supercritical fluid that is exhausted from the body 410 may be installed in the exhaust line 452. The supercritical fluid that is exhausted through the exhaust line 452 may be discharged to the atmosphere or may be provided to a supercritical fluid recycle system (not shown) that recycles used supercritical fluid.

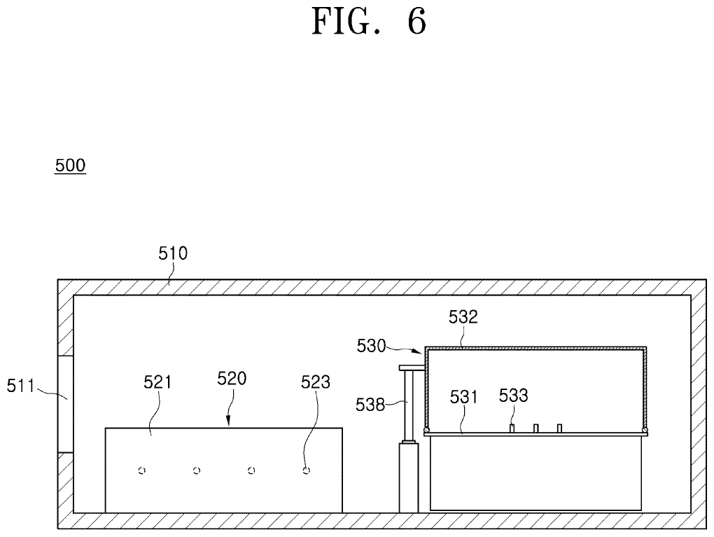

FIG. 6 is a side cross-sectional view showing the heat treatment module 500 shown in FIG. 1.

The heat treatment module 500 can perform a heat treatment process on a substrate W treated by the substrate treatment module 100. For example, the heat treatment module 500 may perform a hard bake process of heating a substrate W after a developing process is performed, and a cooling process of cooling a heated substrate after the bake process. The heat treatment process may include a cooling process and a heating process. Referring to FIG. 6, the heat treatment module 500 includes a housing 510, a cooling unit 520, and a heating unit 530.

The housing 510 can provide a treatment space in which the heat treatment process is performed. For example, the housing 510 may be provided in a rectangular prism shape. The housing 510 may include an entrance 511 formed on the surface facing the transfer module 24. The entrance 511 provides a passage for movement of substrates W.

The cooling unit 520 may include a cooling plate 521 on which a substrate W is seated. The cooling plate 521 may have a substantially circular shape when seen from above. The cooling plate may be provided with a cooling member. According to an embodiment, the cooling member may be provided as a channel that is formed in the cooling plate and through which cooling fluid flows. The cooling plate may be made of a metal material having high thermal conductivity.

The heating unit 530 may have a heating plate 531, a cover 532, lift pins 533, and an actuator 538. The heating unit 530 can heat a substrate W at a setting temperature. The heating plate 531 may have a substantially circular shape when seen from above. For example, the heating plate 531 may have a larger diameter than substrates W. A heating member for heating substrates W may be provided in the heating plate 531. For example, the heating member may be provided as a heating coil. Alternatively, the heating plate 531 may be provided with heating patterns. The heating plate 531 may be provide with the lift pins 533 that can be driven in the up-down direction in the third direction 6.

The cover 532 is positioned over the heating plate 531. The cover 532 may be provided with a cylindrical shape having an internal space and having an open lower portion. The cover 532 provides a heating space therein, is positioned over the heating plate 531, and can be moved in the up-down direction by the actuator 538. When the cover 532 comes in contact with the heating plate 531, the space surrounded by the cover 532 and the heating plate 531 can be provided as a heating space for heating substrates W.

The lift pins 533 can be moved up and down by a separate pin driving unit. The lift pins 533 can seat a substrate W onto the heating plate 531. The lift pins 533 can move up a substrate W at a position spaced a predetermined distance apart from the heating plate 531. According to an embodiment, three lift pins 533 may be provided.

The actuator 538 is coupled and fixed to the cover 532, and can move up and down the cover 532 when a substrate W is conveyed or transferred to the heating plate 531. For example, the actuator 538 may be provided as a cylinder.

Though not shown in detail, the heat treatment module 500 of FIG. 6 may further include a transfer plate for transferring substrates W between the cooling unit 520 and the heating unit 530. The transfer plate (not shown) is provided substantially in a disc shape and may have a diameter corresponding to substrates W.

Selectively, some of the heat treatment modules 500 may have only a cooling plate and the others may have only a heating plate.

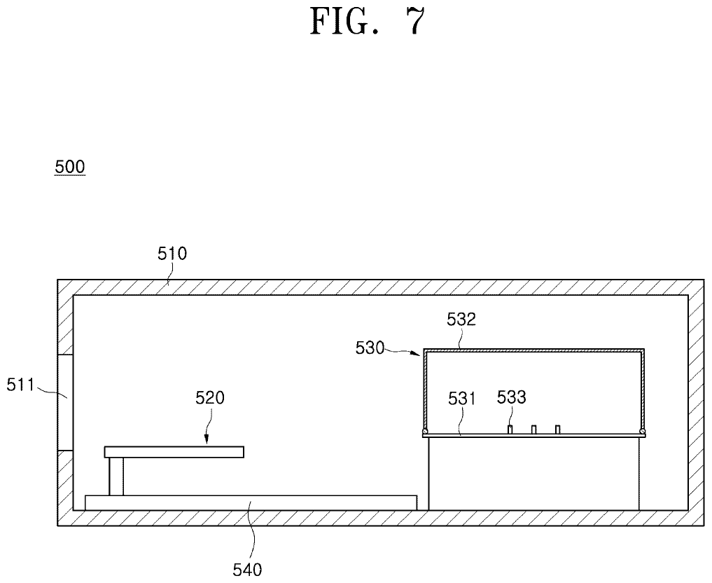

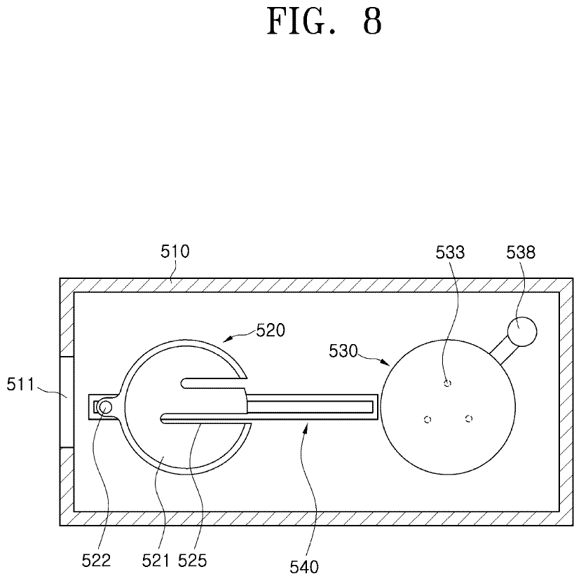

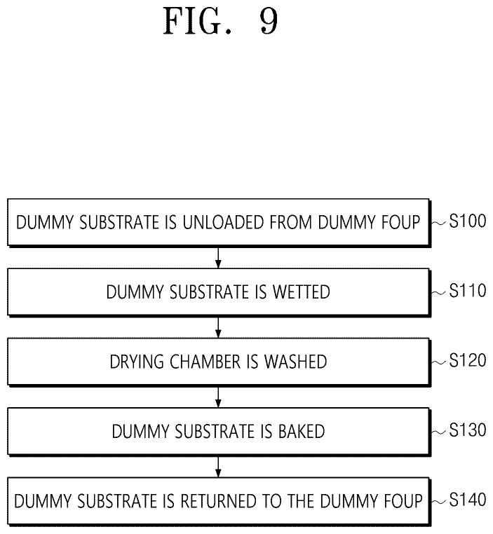

FIGS. 7 and 8 are views showing another example of the heat treatment module 500. FIG. 7 is a side cross-sectional view showing another example of the heat treatment module 500 and FIG. 8 is a plan view showing another example of the heat treatment module 500.

Referring to FIGS. 7 and 8, the cooling unit 520 may further include a transferring unit 540 that moves the cooling plate 521. The transferring unit 540 can transfer the cooling plate 521 in the housing 510. The cooling plate 521 can be moved to a standby position and a cooling position by the transferring unit 540. The standby position may be a position adjacent to the entrance 511 and the cooling position may be a position adjacent to the heating unit 530. The transferring unit 540 can replace the transfer plate provided to transfer substrates W between the cooling unit 520 and the heating unit 530 in the heat treatment module 500.

A substrate W is placed on the cooling plate 521. The cooling plate 521 may be provided in a circular shape. For example, the cooling plate 521 may be provided with the same size as substrates W. The cooling plate 521 may be made of a metal material having high thermal conductivity. A guide hole 525 may be formed at the cooling plate 521 coupled to the transferring unit 540 by the supporting unit 522. The guide hole 525 is provided to extend from the outer side of the cooling plate 521 to the inside of the cooling plate 521. The guide hole 525 prevents interference or collision with the lift pins 553 when the cooling plate 521 is moved over the heating plate 531. A channel 524 through which a refrigerant (cooling water) flows may be provided in the cooling plate 521.

Other components are the same as the heat treatment module 500 shown in FIG. 6, so they are not described.

Meanwhile, it was exemplarily described in this specification that the cooling unit 520 and the heating unit 530 are arranged in parallel with the longitudinal direction of the guide rail 242 (first direction 2) in the heat treatment module 500, but the cooling unit 520 and the heating unit 530 may be disposed in the second direction 4 perpendicular to the first direction 2. For example, the cooling unit 520 may be positioned close to the transfer module 24 in comparison to the heating unit 530.

As described above, it is possible to reduce environmental variation that may be generated to substrates by disposing the liquid treatment unit 300 and the supercritical treatment unit 400 for performing developing treatment on substrates in one internal space and configuring them in one module. Further, it is possible to reduce the operation time of the main robot 244. Accordingly, the treatment time accompanying transferring of substrates is reduced, the output can be increased and the process ability of the facility can be improved.

A controller 90 (see FIG. 1) can control the substrate treatment apparatus. The ontroller90 may include: a process controller that is a microprocessor (computer) that performs control of the substrate treatment apparatus; a user interface that is a keyboard through which an operator performs command input operation, etc. to manage the substrate treatment apparatus, a display that visualizes and displays the operation situation of the substrate treatment apparatus, etc.; and a memory that stores a control program for performing treatment, which is performed in the substrate treatment apparatus, under control of the process controller, a program for performing treatment on each component in accordance with various data and treatment conditions, that is, a treatment recipe. Further, the user interface and the memory may be connected to the process controller. The treatment recipe may be stored in a memory medium of the memory unit and the memory medium may be a hard disk and may be a portable disc such as a CD-ROM and a DVD, and a semiconductor memory such as a flash memory.

The ontroller90 can control the substrate treatment apparatus to clean the treatment space of the supercritical treatment unit 400 using a dummy substrate accommodated in the dummy carrier DF in accordance with preset conditions. The ontroller90 can control the substrate treatment apparatus such that a dummy substrate used to clean the supercritical treatment unit 400 is recovered to the dummy carrier DF after heat treatment in the heat treatment unit 300. The ontroller90 can control the substrate treatment apparatus to wet a dummy substrate with a cleaning chemical in the liquid treatment unit 300, load the dummy substrate wet with the cleaning chemical into the supercritical treatment unit 400, and supply supercritical fluid to the supercritical treatment unit 400 such that the treatment space of the supercritical treatment unit 400 is washed.

The ontroller90 can control the substrate treatment apparatus to be able to perform the substrate treatment method to be described below.

The substrate treatment method in the substrate treatment apparatus having the configuration described above is as follows.

The substrate treatment method may include a step of performing developing treatment by applying a developer to a substrate in the liquid treatment unit 300 and a step of performing drying treatment using supercritical fluid on the developed substrate in the supercritical treatment unit 400. Further, the substrate treatment method determines the cleaning time point of the supercritical treatment unit 400 on the basis of a process recipe rather than units.

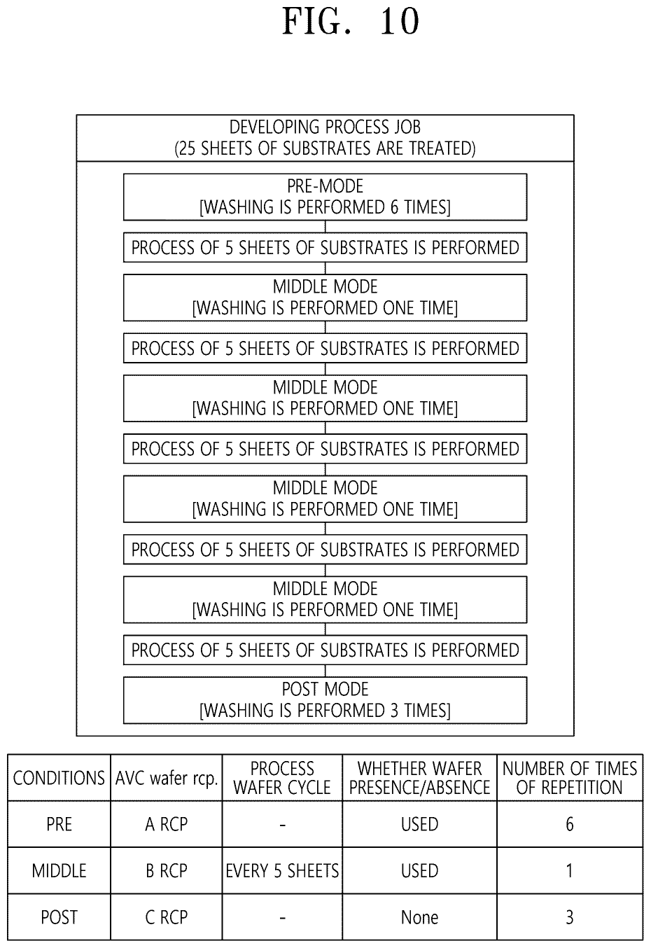

FIG. 10 is a flowchart illustrating a washing process of a drying chamber and a table showing a cleaning recipe according to development process job reference time points.

Referring to FIGS. 10, the substrate treatment method can clean the supercritical treatment unit 400 by dividing a time point into three steps of pre, middle, and post. The washing time point of the supercritical treatment unit 400 may include a pre-mode that is performed before a preset developing process job of substrates is started, a middle mode that is performed during the developing process job of substrates, and a post-mode that is performed after the developing process job of substrates is finished.

Different washing numbers of times and washing recipes may be set in accordance with conditions for the pre-mode, the middle mode, and the post-mode. For example, the washing recipe may include temperature, pressure, the type of chemical, time, the amount of supercritical fluid, and the number of times of repetition of injection and discharge of supercritical fluid.

Describing the washing process of the supercritical fluid unit 400, the washing process may include a step of unloading a dummy substrate from the dummy carrier DF and loading the substrate into the liquid treatment unit 300 (S100), wetting the dummy substrate with a chemical in the liquid treatment unit 300 (S110), a step of washing the treatment space of the supercritical fluid unit 400 by loading the dummy substrate wet with the chemical into the supercritical fluid unit 400 and then by supplying supercritical fluid to the supercritical fluid unit 400 (S120), a step of performing bake treatment in the heat treatment module 500 to reuse the dummy substrate used to wash the supercritical fluid unit 400 (S130), and a step of returning the baked dummy substrate to the dummy carrier DF (S140). Transfer of a dummy substrate from the liquid treatment unit 300 to the supercritical fluid unit 400 is provided by the transfer unit 600.

The chemical that wets a dummy substrate in the liquid treatment unit 300 may include an organic solvent. The supercritical fluid that is supplied to the treatment space in the supercritical fluid unit 400 may include carbon dioxide (CO₂), water (H₂O), methane (CH₄), ethane (C₂H₆), propane (C₃H₈), ethylene (C₂H₄), propylene (C₃H₆), methanol (CH₃OH), ethanol (C₂H₅OH), sulfur hexafluoride (SF₆), acetone (C₃H₆O), etc. Heat treatment can be performed on a dummy substrate at 110° C. or higher in the heat treatment module 400. As described above, by performing heat treatment on a dummy substrate used in the supercritical fluid unit 400, it is possible to reuse a dummy substrate and increase the number of times of reuse of a dummy substrate.

The pre-mode has a more number of times of washing than the middle mode and the post-mode, thereby being able to improve the temperature and pressure profiles of the supercritical fluid unit 400 up to a process level. For example, the pre-mode can repetitively clean the supercritical fluid unit 400 six times. The middle mode can set a different cycle from the pre-mode and the post-mode. For example, when a user sets a washing cycle as 5 sheets, the middle mode cleans the supercritical fluid unit 400 every time a process is finished for five sheets of substrates.

For example, when 25 sheets of substrates are treated, it is possible to repeat a process of treating 5 sheets of substrates and then cleaning the supercritical fluid unit 400 one time after the pre-mode, and treating 5 sheets of substrates again and then cleaning the supercritical fluid unit 400 one time. Further, after the last 5 sheets of substrates are treated, the post-mode proceeds. The post-mode is a time point after treatment is finished for 25 sheets of substrates and cleans the supercritical fluid unit 400 three times after all of processes are finished. In the post-mode, the supercritical fluid unit 400 may be cleaned without a dummy substrate.

The specification provides examples of the present invention. Further, the description provides an embodiment of the present invention and the present invention may be used in other various combination, changes, and environments. That is, the present invention may be changed or modified within the scope of the present invention described herein, a range equivalent to the description, and/or within the knowledge or technology in the related art. The embodiment shows an optimum state for achieving the spirit of the present invention and may be changed in various ways for the detailed application fields and use of the present invention. Therefore, the detailed description of the present invention is not intended to limit the present invention in the embodiment. Further, the claims should be construed as including other embodiments.

1. A substrate treatment method comprising washing a drying chamber comprising:
wetting a dummy substrate with a chemical in a liquid treatment chamber;
washing a treatment space of the drying chamber by loading the dummy substrate wet with the chemical into the drying chamber and then supplying supercritical fluid to the drying chamber; and
performing bake treatment to reuse the dummy substrate used to wash the drying chamber.

2. The substrate treatment method of claim 1, further comprising:
unloading the dummy substrate from a dummy FOUP and loading the dummy substrate into the liquid treatment chamber; and
returning the baked dummy substrate to the dummy FOUP.

3. The substrate treatment method of claim 2, wherein the chemical wetting the dummy substrate comprises an organic solvent.

4. The substrate treatment method of claim 2, wherein the supercritical fluid comprises carbon dioxide.

5. The substrate treatment method of claim 2, wherein heat treatment is performed on the dummy substrate at 110° C. or higher in the bake treatment.

6. The substrate treatment method of claim 1, wherein the washing of the drying chamber comprises a pre-mode that is performed before a preset developing process job of substrates is started, a middle mode that is performed during the developing process job of substrates, and a post-mode that is performed after the developing process job of substrates is finished.

7. The substrate treatment method of claim 6, wherein different washing numbers of times and washing recipes are set in accordance with conditions for the pre-mode, the middle mode, and the post-mode, and
the washing recipe comprises temperature, pressure, the type of chemical, time, the amount of supercritical fluid, and the number of times of repetition of injection and discharge of supercritical fluid.

8. The substrate treatment method of claim 6, wherein the pre-mode has a more number of times of washing than the middle mode and the post-mode.

9. The substrate treatment method of claim 7, wherein the drying chamber is washed every time a predetermined number of sheets of substrates are treated in the middle mode.

10. The substrate treatment method of claim 6, wherein the developing process job comprises:
performing developing treatment by applying a developer to the substrate in the liquid treatment chamber; and
performing drying treatment on the developed substrate using supercritical fluid in the drying chamber.

11.-16. (canceled)

17. A substrate treatment method comprising:
performing developing treatment by applying a developer to the substrate in a liquid treatment chamber;
performing drying treatment on the developed substrate using supercritical fluid in a drying chamber; and
washing the drying chamber,
wherein the washing of the drying chamber comprises:
unloading a dummy substrate from a dummy FOUP and loading the dummy substrate into the liquid treatment chamber;
wetting the dummy substrate with a chemical in the liquid treatment chamber;
washing a treatment space of the drying chamber by loading the dummy substrate wet with the chemical into the drying chamber and then supplying supercritical fluid to the drying chamber;
performing bake treatment to reuse the dummy substrate used to wash the drying chamber; and
returning the baked dummy substrate to the dummy FOUP.

18. The substrate treatment method of claim 17, wherein the washing of the drying chamber comprises a pre-mode that is performed before a preset developing process job of substrates is started, a middle mode that is performed during the developing process job of substrates, and a post-mode that is performed after the developing process job of substrates is finished.

19. The substrate treatment method of claim 18, wherein the chemical wetting the dummy substrate comprises an organic solvent,
the supercritical fluid comprises carbon dioxide, and
heat treatment is performed on the dummy substrate at 110° C. or higher in the bake treatment.

20. The substrate treatment method of claim 18, wherein different washing numbers of times and washing recipes are set in accordance with conditions for the pre-mode, the middle mode, and the post-mode,
the washing recipe comprises temperature, pressure, the type of chemical, time, the amount of supercritical fluid, and the number of times of repetition of injection and discharge of supercritical fluid, and
the pre-mode performs a more number of times of washing than the middle mode and the post-mode.
